(19) United States
(12) Patent Application Publication
(10) Pub. No.: US 2024/0410050 A1
(43) Pub. Date: Dec. 12, 2024

(54) STAGE STRUCTURE, SUBSTRATE PROCESSING APPARATUS, AND TEMPERATURE CONTROL METHOD

(71) Applicant: Tokyo Electron Limited, Tokyo (JP)

(72) Inventors: Naoki WATANABE, Tokyo (JP); Tatsuo HATANO, Yamanashi (JP)

(21) Appl. No.: 18/673,988

(22) Filed: May 24, 2024

(30) Foreign Application Priority Data
Jun. 7, 2023 (JP) 2023-094319

(51) Int. Cl. C23C 14/54; C23C 14/50

(52) U.S. Cl. CPC C23C 14/541; C23C 14/50

(57) ABSTRACT

A stage structure includes a plurality of stages respectively configured to support a substrate placed thereon, a single cooling plate common to the plurality of stages, a refrigerator configured to cool the cooling plate, and an elevating device configured to thermally connect or separate a first contact surface of the plurality of stages and a second contact surface of the cooling plate.

### CROSS-REFERENCE TO RELATED APPLICATIONS

This application is based upon and claims priority to Japanese Patent Application No. 2023-094319, filed on Jun. 7, 2023, the entire contents of which are incorporated herein by reference.

### BACKGROUND

### 1. Field of the Invention

The present disclosure relates to stage structures, substrate processing apparatuses, and temperature control methods.

### 2. Description of the Related Art

As an example, Japanese Laid-Open Patent Publication No. 2020-47624 proposes a substrate placing mechanism that places a substrate on which a film is formed in a film forming apparatus. The substrate placing mechanism includes a placing table having a substrate placing surface on which the substrate is placed, a cooling head provided opposite to the substrate placing surface of the placing table and cooled to a very low temperature by a refrigerator, a contacting and separating mechanism that causes the placing table to make contact with or separate from the cooling head, a rotating mechanism that rotates the placing table, and a controller. The controller controls the contacting and separating mechanism to a state where the placing table makes contact with the cooling head during times other than a film forming process, and the substrate is placed on the placing table in this state. On the other hand, during the film forming process, the controller controls the contacting and separating mechanism to a state where the placing table is separated from the cooling head, and the placing table is rotated in this state by the rotating mechanism.

### SUMMARY

One aspect of the present disclosure provides a stage structure, a substrate processing apparatus, and a temperature control method for cooling a stage on which a substrate is placed.

According to one aspect of the present disclosure, a stage structure includes a plurality of stages respectively configured to support a substrate placed thereon; a single cooling plate common to the plurality of stages; a refrigerator configured to cool the cooling plate; and an elevating device configured to thermally connect or separate a first contact surface of the plurality of stages and a second contact surface of the cooling plate.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a configuration example of a substrate processing apparatus including a stage structure according to one embodiment;

FIG. 2 is a block diagram illustrating a heater controller for controlling a heater;

FIG. 3A and FIG. 3B are graphs illustrating examples of temperature control;

FIG. 4 is a graph illustrating an example of a temperature change of a stage in a reference example;

FIG. 5 is a graph illustrating an example of a temperature change of the stage in one embodiment;

FIG. 6A. FIG. 6B, FIG. 6C, and FIG. 6D are schematic cross sectional views illustrating examples of states of the stage during various processes;

FIG. 7 is a time chart illustrating an example of an operation of the substrate processing apparatus;

FIG. 8 is a schematic diagram illustrating an example of the stage structure;

FIG. 9 is a schematic diagram illustrating another example of the stage structure; and

FIG. 10 is an enlarged view illustrating an example of a shape of a through hole.

### DETAILED DESCRIPTION

Hereinafter, embodiments for implementing the present disclosure will be described with reference to the drawings. In the drawings, the same constituent elements are designated by the same reference numerals, and a redundant description thereof may be omitted.

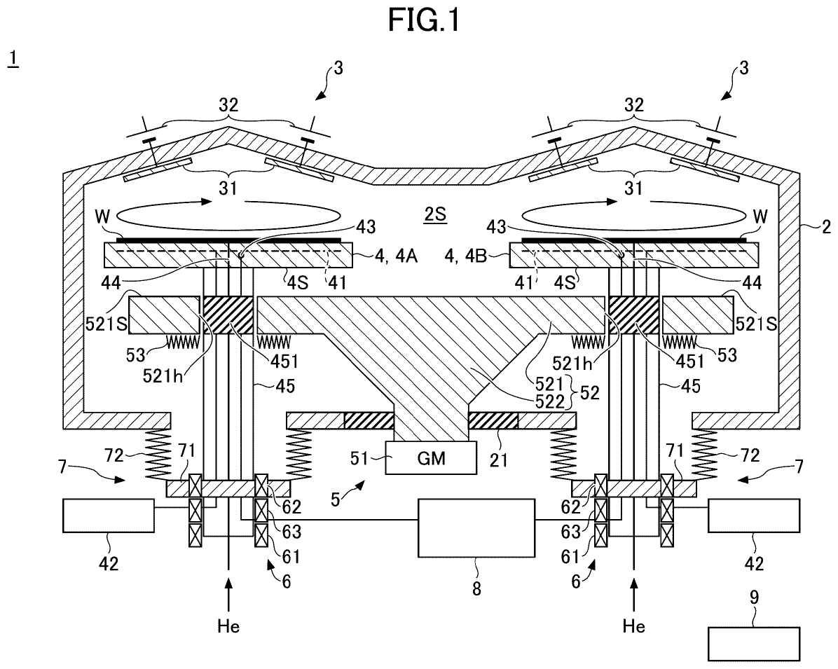

An example of a substrate processing apparatus 1 including a stage structure according to one embodiment will be described with reference to FIG. 1. FIG. 1 is a cross sectional view illustrating a configuration example of the substrate processing apparatus 1 including the stage structure according to the present embodiment.

As illustrated in FIG. 1, the substrate processing apparatus 1 may be a substrate processing apparatus (for example, a physical vapor deposition (PVD) apparatus or the like) that performs a desired process (for example, a film forming process or the like) on a substrate W by supplying a processing gas into a processing chamber 2 and sputtering a target 31 provided inside the processing chamber 2. The substrate processing apparatus 1 including the stage structure according to the present embodiment will be described for an example of a case where the substrate processing apparatus 1 is a PVD apparatus. However, the substrate processing apparatus 1 is not limited to the PVD apparatus, and may be a substrate processing apparatus (for example, a chemical vapor deposition (CVD) apparatus, an atomic layer deposition (ALD) apparatus, or the like) that performs a desired process (for example, a film forming process or the like) on the substrate W by supplying a processing gas into the processing chamber 2.

The substrate processing apparatus 1 includes the processing chamber 2, a sputtered particle emission section 3, a plurality of stages 4 (4A and 4B) on which substrates W are placed, one freezer 5 common to the plurality of stages 4, a stage rotating mechanism 6 for rotating the plurality of stages 4, a stage elevating mechanism 7 for elevating the plurality of stages 4, a heater controller 8, and a controller 9. In the substrate processing apparatus 1, a structure that supports the substrate W is also referred to as a stage structure. Specifically, the stage structure includes the plurality of stages 4 (4A and 4B), the freezer 5, the stage rotating mechanism 6, the stage elevating mechanism 7, and the heater controller 8.

The processing chamber 2 forms an internal space 2S. The processing chamber 2 is configured so that a pressure of the internal space 2S is reduced to an ultrahigh vacuum by operating an exhaust device (not illustrated), such as a vacuum pump or the like. In addition, the processing chamber 2 has a gas introduction port (not illustrated) supplied with a processing gas from a processing gas supply. In the PVD apparatus, a sputtering gas (for example, an inert gas) is introduced as the processing gas into the internal space 2S through the gas introduction port.

The sputtered particle emission section 3 includes a target 31, and a sputtering power source 32. The target 31 is made of a material including a constituent element of a film to be formed. The target 31 is held by a conductive target holder (not illustrated). The target holder is held inside the processing chamber 2 via an insulating member (not illustrated). The sputtering power source 32 is electrically connected to the target holder. The sputtering power source 32 may be a DC power source in a case where the target 31 is made of a conductive material, and may be a high-frequency power source in a case where the target 31 is made of a dielectric material. In the case where the sputtering power source 32 is the high-frequency power source, the sputtering power source 32 is connected to the target holder via a matching circuit. When a voltage is applied to the target holder, the sputtering gas is dissociated in a periphery of the target 31. Further, ions within the dissociated sputtering gas collide with the target 31, and particles of a constituent material of the target 31 are emitted from the target 31 as sputtered particles.

A plurality of stages 4 (4A, 4B) on which the substrates W are placed are provided inside the processing chamber 2. In the example illustrated in FIG. 1, the substrate processing apparatus 1 includes two stages 4A and 4B. The stage 4 is formed of a material (for example, copper (pure copper), aluminum, or the like) having a high thermal conductivity. In addition, a heat capacity of the stage 4 is sufficiently large compared to that of the substrate W.

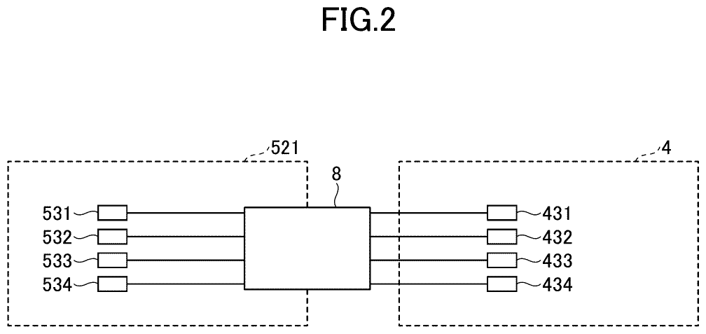

Moreover, the stage 4 includes an electrostatic chuck. The electrostatic chuck has a chuck electrode 41 embedded in a dielectric film. The chuck electrode 41 is connected to a chuck power source 42 via a slip ring 63 which will be described later, and may be applied with a predetermined potential. According to this configuration, the substrate W can be attracted to the electrostatic chuck, and the substrate W can be fixed to an upper surface (a substrate placing surface) of the stage 4. In addition, the stage 4 can be arranged at either a raised position or a lowered position by the stage elevating mechanism 7. The raised position is a position where a first contact surface 4S of the stage 4 and a second contact surface 521S of a cooling plate 52 which will be described later are separated from each other. The raised position is a position (a stage rotating position) where the stage 4 can be rotated by the stage rotating mechanism 6. The lowered position is a position (a stage cooling position) where the first contact surface 4S of the stage 4 and the second contact surface 521S of the cooling plate 52 which will be described later are thermally connected to each other. In the example illustrated in FIG. 1, the first contact surface 4S is formed on a surface (a lower surface or a rear surface) opposite to the substrate placing surface (the upper surface) of the stage 4. Further, a temperature sensor 43 for detecting a temperature of the stage 4 is provided in the stage 4. The temperature sensor 43 is connected to the heater controller 8 via the slip ring 63 which will be described later. As illustrated in FIG. 2 which will be described later, a plurality of temperature sensors 43 are provided on each stage 4.

The stage 4 includes a heat transfer gas supply 44 that supplies a heat transfer gas (for example, He gas) to a gap between a rear surface of the substrate W and the placement surface of the stage 4.

A support column 45 for supporting the stage 4 is provided at a center of the surface of the stage 4 opposite to the substrate placing surface. A part of the support column 45 has a heat insulator 451 formed of a heat insulating member. The support column 45 serves as a rotating shaft for rotating the stage 4.

The freezer 5 is provided below the stage 4. The freezer 5 includes a refrigerator 51, and the cooling plate 52.

The refrigerator 51 is provided outside the processing chamber 2. From a viewpoint of cooling capacity, it is preferable to utilize a Gifford-McMahon (GM) cycle for the refrigerator 51.

The cooling plate 52 includes a plate portion 521, and a heat transfer portion 522. The cooling plate 52 is formed of a material having a high thermal conductivity (for example, copper (pure copper), aluminum, or the like). In addition, the plate portion 521 and the heat transfer portion 522 may be integrally formed, or may be formed by thermally connecting separately formed members. A heat capacity of the cooling plate 52 is sufficiently large compared to that of the stage 4.

The plate portion 521 has a plurality of through holes 521h through which the support columns 45 are inserted, respectively. One through hole 521h is formed for each support column 45. The plate portion 521 has the second contact surface 521S that is thermally connected to the first contact surface 4S of the stage 4. In the example illustrated in FIG. 1, the second contact surface 521S is formed on an upper surface of the plate portion 521. In addition, the second contact surface 521S is formed in a periphery of the through hole 521h. One end of the heat transfer portion 522 is connected to the plate portion 521. The other end of the heat transfer portion 522 penetrates a bottom wall of the processing chamber 2, and is thermally connected to the refrigerator 51. A heat insulating member 21 is provided between the bottom wall of the processing chamber 2 and the heat transfer portion 522.

According to such a configuration described above, the refrigerator 51 cools the second contact surface 521S of the cooling plate 52 to a very low temperature. The refrigerator 51 cools the stage 4 arranged at the lowered position, via the cooling plate 52.

A heater 53 for heating the plate portion 521 is provided on a rear surface (the surface on the opposite to the second contact surface 521S) of the plate portion 521. As illustrated in FIG. 2 which will be described later, a plurality of heaters 53 are provided with respect to each stage 4.

The stage rotating mechanism 6 includes a motor 61, a magnetic fluid seal 62, and the slip ring 63.

The motor 61 is provided below an elevating plate 71 which will be described later, and rotates the support column 45 to rotate the stage 4. The motor 61 is a direct drive (DD) motor, for example. The stage rotating mechanism 6 for rotating the support column 45 may have a structure other than that using the direct drive motor, and may have a structure that rotates the support column 45 using a servo motor and a transmission belt, for example.

The support column 45 penetrates the elevating plate 71. The magnetic fluid seal 62 is provided between the support column 45 and the elevating plate 71. The magnetic fluid seal 62 rotatably supports the support column 45, and seals in between the support column 45 and the elevating plate 71 to separate the internal space 2S of the processing chamber 2 from an exterior space of the processing chamber 2.

According to such a configuration described above, the stage rotating mechanism 6 rotates the stage 4 by rotating the support column 45 by the motor 61.

The slip ring 63 transmits an electric signal from the temperature sensor 43 provided in the stage 4, via a signal line provided in the support column 45. The slip ring 63 also transmits an electric power to the chuck electrode 41 provided in the stage 4, via a power line provided in the support column 45. In other words, the support column 45 has interconnects including the signal line and the power line.

The stage elevating mechanism 7 includes an elevating plate 71, a bellows 72, and an elevation drive (not illustrated). The elevating plate 71 rotatably supports the support column 45 via the magnetic fluid seal 62. The bellows 72 seals in between the elevating plate 71 and the processing chamber 2 to separate the internal space 2S of the processing chamber 2 from the exterior space of the processing chamber 2. The elevating driver raises or lowers the elevating plate 71. Thus, the elevating driver raises or lowers the stage 4. The elevating driver may have a structure that raises or lowers the stage 4 using a ball screw and a servo motor, for example.

According to such a configuration described above, the stage elevating mechanism 7 raises the stage 4 to the elevated position by elevating the elevating plate 71 by the elevating driver, and lowers the stage 4 to the lowered position by lowering the elevating plate 71 by the elevating driver.

The heater controller 8 controls the heater 53 (531 through 534) based on the temperature detected by the temperature sensor 43.

The controller 9 may be a computer, for example, and includes a central processing unit (CPU), a random access memory (RAM), a read only memory (ROM), an auxiliary storage device, or the like. The CPU executes a program stored in the ROM or the auxiliary storage device, and controls the operation of the substrate processing apparatus 1. The controller 9 may be provided inside or outside the substrate processing apparatus 1. In a case where the controller 9 is provided outside the substrate processing apparatus 1, the controller 9 can control the substrate processing apparatus 1 via a communication circuit or means, such as a wired or wireless communication circuit or means.

According to such a configuration described above, the stage structure cools the stage 4 by lowering the stage 4 to the lowered position by the stage elevating mechanism 7, and thermally connecting the first contact surface 4S of the stage 4 and the second contact surface 521S of the cooling plate 52. In addition, the stage structure separates the first contact surface 4S of the stage 4 and the second contact surface 521S of the cooling plate 52 from each other, by raising the stage 4 to the raised position by the stage elevating mechanism 7. Moreover, the stage structure rotates the stage 4 by the stage rotating mechanism 6 in a state where the stage 4 is arranged at the raised position.

Further, the stage structure can prevent an increase in a diameter of the support column 45. In other words, it is possible to prevent an increase in diameters of the direct drive motor 61, the magnetic fluid seal 62, and the slip ring 63. In addition, the cooling position (lowered position) of the stage 4 and the rotating position (raised position) of the stage 4 can be switched without using an elevating mechanism for raising and lowering the freezer 5 (the refrigerator 51 and the cooling plate 52).

Next, examples of temperature control by the heater controller 8 will be described with reference to FIG. 2 through FIG. 5.

FIG. 2 is a block diagram for explaining the heater controller 8 for controlling the heater 53.

The temperature sensors 43 include a first inner temperature sensor 431 and a first outer temperature sensor 432 provided on the first stage 4A, and a second inner temperature sensor 433 and a second outer temperature sensor 434 provided on the second stage 4B. The first inner temperature sensor 431 measures the temperature of the first stage 4A in a region close to a rotation center of the first stage 4A. The first outer temperature sensor 432 measures the temperature of the first stage 4A in a region far from the rotation center of the first stage 4A. The second inner temperature sensor 433 measures the temperature of the second stage 4B in a region close to a rotation center of the second stage 4B. The second outer temperature sensor 434 measures the temperature of the second stage 4B in a region far from the rotation center of the second stage 4B.

The heater 53 includes a first inner heater 531 and a first outer heater 532 corresponding to the first stage 4A, and a second inner heater 533 and a second outer heater 534 corresponding to the second stage 4B.

The first inner heater 531 is provided in an annular region concentric with the through hole 521h through which the support column 45 of the first stage 4A is inserted. In addition, the first outer heater 532 is provided in an annular region, concentric with the through hole 521h through which the support column 45 of the first stage 4A is inserted, and located on an outer side of the region where the first inner heater 531 is provided. The second inner heater 533 is provided in an annular region concentric with the through hole 521h of the second stage 4B through which the support column 45 is inserted. Moreover, the second outer heater 534 is provided in an annular region, concentric with the through hole 521h through which the support column 45 of the second stage 4B is inserted, and located on an outer side of the region where the second inner heater 533 is provided.

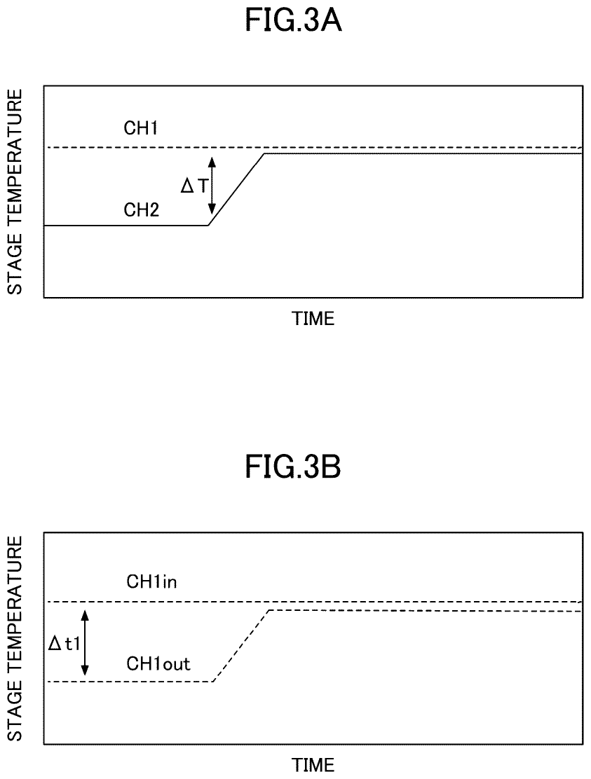

FIG. 3A and FIG. 3B are graphs illustrating examples of temperature control. In FIG. 3A and FIG. 3B, the abscissa indicates the time, and the ordinate indicates the temperature of the stage 4. In these examples, the stage 4 is lowered by the stage elevating mechanism 7, and the first contact surface 4S and the second contact surface 521S make thermal contact with each other.

In FIG. 3A, CH1 indicated by a broken line denotes a temperature detected by the first inner temperature sensor 431, and CH2 indicated by a solid line denotes a temperature detected by the second inner temperature sensors 433.

In this example, the temperature of the stage 4A indicated by CH1 has a temperature difference ΔT with respect to the temperature of the stage 4B indicated by CH2. In this case, the heater controller 8 increases the amount of electric power supplied to the heater detecting a lower temperature. In this example, the amount of electric power supplied to the second inner heater 533 is increased. In other words, the amount of electric power supplied to the second inner heater 533 is set higher than the amount of electric power supplied to the first inner heater 531. Accordingly, the temperature is adjusted until the temperature of the stage 4B indicated by CH2 becomes equal to the temperature of the stage 4A indicated by CH1.

Although the temperature difference in the inner regions detected by the first inner temperature sensor 431 and the second inner temperature sensor 433 is adjusted in the above example, the present invention is not limited to such an adjustment. The temperature difference in the outer regions detected by the first outer temperature sensor 432 and the second outer temperature sensor 434 may be adjusted in a similar manner. Hence, the electric power supplied to the first heater (531 or 532) or the second heater (533 or 534), corresponding to the temperature sensor detecting a lower temperature between the temperature sensor (431 or 432) of one stage 4A and the temperature sensor (433 or 434) of the other stage 4B, is increased. As a result, it is possible to reduce the temperature difference between the stages 4.

In FIG. 3B, CH1in indicated by a broken line denotes a temperature detected by the first inner temperature sensor 431, and CH1out indicated by a broken line denotes a temperature detected by the first outer temperature sensor 432.

In this example, an inner temperature of the stage 4A indicated by CH1in has a temperature difference Δt1 with respect to an outer temperature of the stage 4A indicated by CH1out. In this case, the heater controller 8 increases the amount of electric power supplied to the heater detecting a lower temperature. In this example, the amount of electric power supplied to the first outer heater 532 is increased. In other words, the amount of electric power supplied to the first outer heater 532 is set higher than the amount of electric power supplied to the first inner heater 531. Accordingly, the temperature is adjusted until the outer temperature of the stage 4A indicated by CH1out becomes equal to the inner temperature of the stage 4A indicated by CH1in.

Although the temperature difference between the inner temperature and the outer temperature of the first stage 4A is adjusted in the above example, the present invention is not limited to such an adjustment. The temperature difference between the inner temperature and the outer temperature of the second stage 4B may be adjusted in a similar manner. As a result, it is possible to reduce the temperature difference within a single stage 4.

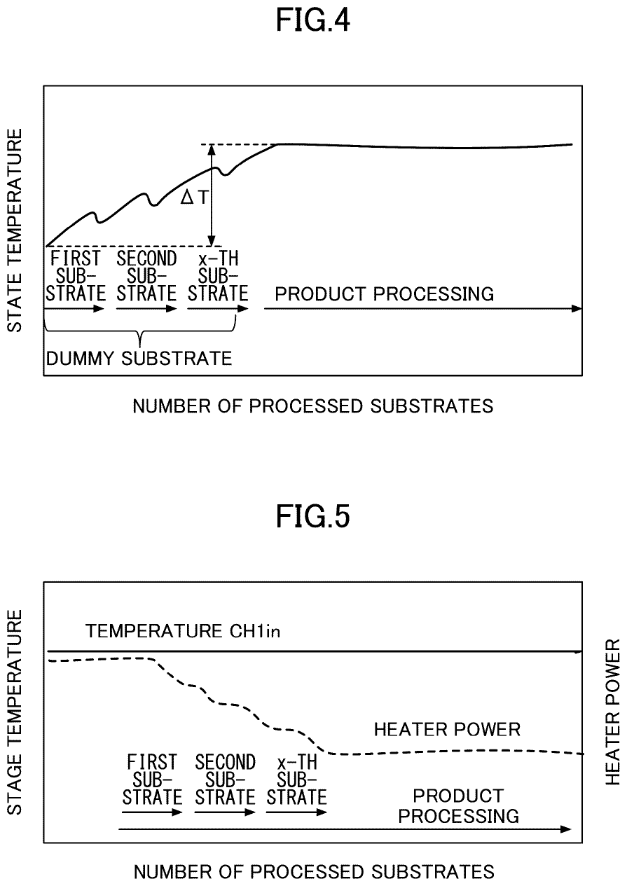

Next, a temperature change of the cooling plate 52 when continuously performing the substrate processing with respect to a plurality of substrates W will be described with reference to FIG. 4 and FIG. 5.

FIG. 4 is a graph illustrating an example of a temperature change of the stage 4 in a reference example. In FIG. 4, the abscissa indicates a number of substrates W processed, and the ordinate indicates the temperature of the stage 4.

FIG. 4 illustrates the example of the temperature change of the stage 4 for a case where the temperature adjustment by the heater 53 is not performed. The temperature of the stage 4 rises with the temperature difference ΔT as illustrated in FIG. 4 due to heat input from the temperature of the substrate W being transferred and the plasma during the substrate processing. For this reason, in order to perform the substrate processing at a stable temperature, a predetermined number of dummy substrates are first processed, and after the temperature of the stage 4 becomes stable (equilibrium state), the substrates W that become products are processed (product processing).

FIG. 5 is a graph illustrating an example of a temperature change of the stage 4 in the present embodiment. In FIG. 5, the abscissa indicates the number of substrates W processed, and the ordinate indicates the temperature of the stage 4.

FIG. 5 illustrates the example of the temperature change of the stage 4 for a case where a predetermined electric power is supplied to the heater 53 in advance when starting the substrate processing of a first substrate W. When there is heat input from the temperature of the substrate W being transferred and the plasma during the substrate processing, the heater controller 8 performs a control to reduce the electric power supplied to the heater 53 based on the temperature detected by the temperature sensor 43.

An example of temperature control when a plurality of substrates W are subjected to the substrate processing will be described below.

First, the first substrate W is placed on the stage 4. Next, the stage 4 on which the first substrate W is placed is lowered to the lowered position, to cause the first contact surface 4S and the second contact surface 521S to thermally connect with each other, and the stage 4 and the first substrate W are cooled. In this case, a first electric power is supplied to the heater 53.

Next, the stage 4 on which the first substrate W is placed is raised to the raised position, and the first contact surface 4S and the second contact surface 521S are separated from each other. Then, the substrate processing (film forming processing) is performed on the first substrate W. The first substrate W subjected to the film forming process is unloaded from the processing chamber 2.

Next, a second substrate W is placed on the stage 4. Further, the stage 4 on which the second substrate W is placed is lowered to the lowered position, the first contact surface 4S and the second contact surface 521S are thermally connected to each other, and the stage 4 and the second substrate W are cooled. In this state, the temperature of the stage 4 is high due to the heat input from the substrate processing performed on the first substrate W. Thus, a second electric power lower than the first electric power is supplied to the heater 53. As a result, it is possible to improve a cooling performance of the freezer 5 with respect to the stage 4.

Next, the stage 4 on which the second substrate W is placed is raised to the raised position, and the first contact surface 4S and the second contact surface 521S are separated from each other. Then, the substrate processing (film formation processing) is performed on the second substrate W. The second substrate W subjected to the film forming process is unloaded from the processing chamber 2. Thereafter, the processes described above are repeated until the temperature of the stage 4 becomes stable.

Accordingly, the temperature of the stage 4 becomes stable from the time when the substrate processing of the first substrate W is performed, and the substrate processing can be performed continuously on the plurality of substrates W. That is, compared to the reference example illustrated in FIG. 4, the process of stabilizing the temperature of the stage 4 using the dummy substrates is not required in the present embodiment.

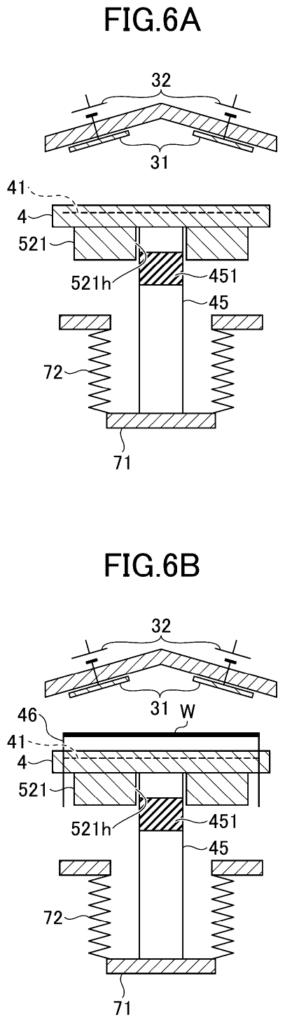

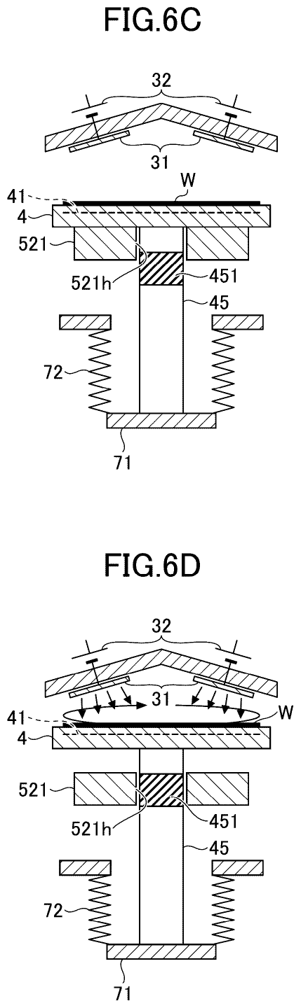

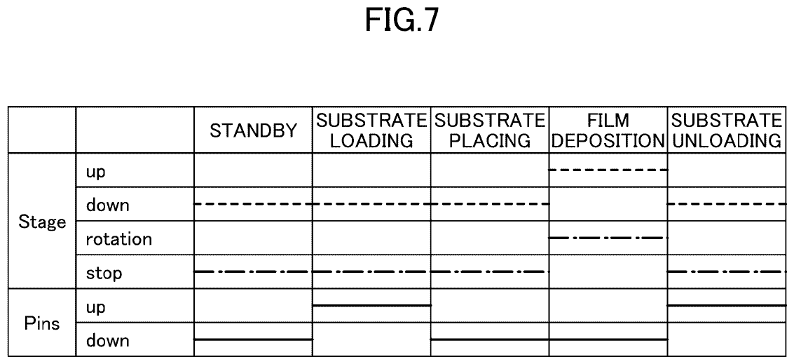

Next, an example of an operation of the substrate processing apparatus 1 will be described with reference to FIG. 6A through FIG. 7. FIG. 6A. FIG. 6B, FIG. 6C, and FIG. 6D are schematic cross sectional views illustrating examples of states of the stage 4 during various processes. FIG. 7 is a time chart illustrating the example of the operation of the substrate processing apparatus 1.

In a standby process or step, the controller 9 stops the rotation of the stage 4 by the stage rotating mechanism 6 (stage stop), and lowers the stage 4 to the lowered position (stage down) by the stage elevating mechanism 7. Accordingly, the first contact surface 4S and the second contact surface 521S make thermal contact with each other, and the stage 4 is cooled. The state of the stage 4 during this standby process is illustrated in FIG. 6A.

In a substrate loading process or step, the controller 9 stops the rotation of the stage 4 by the stage rotating mechanism 6 (stage stop), and lowers the stage 4 to the lowered position (stage down) by the stage elevating mechanism 7, continuing from the standby process described above. Next, the substrate W is transported and loaded into the processing chamber 2 by a transport device (not illustrated). Then, the controller 9 moves a lift pin 46 to a raised position (pin up). Thus, the substrate W is supported by the lift pin 46. Thereafter, the transport device recedes from inside the processing chamber 2. The state of the stage 4 during this substrate loading process is illustrated in FIG. 6B.

In a substrate placing process or step, the controller 9 stops the rotation of the stage 4 by the stage rotating mechanism 6 (stage stop), and lowers the stage 4 to the lowered position (stage down) by the stage elevating mechanism 7, continuing from the substrate loading process described above. Then, the controller 9 moves the lift pin 46 to a lowered position (pin down). Thus, the substrate W is placed on the stage 4. Further, the first contact surface 4S and the second contact surface 521S make thermal contact with each other, and the stage 4 and the substrate W are cooled. The state of the stage 4 during this substrate placing process is illustrated in FIG. 6C.

In a film forming process or step, the controller 9 raises the stage 4 to the raised position (stage up) by the stage elevating mechanism 7, and rotates the stage 4 (stage rotation) by the stage rotating mechanism 6. The controller 9 controls the sputtered particle emission section 3 to emit the sputtered particles. In this example, a heat capacity of the stage 4 is larger than a heat capacity of the substrate W, and the substrate processing can be performed while preventing a temperature rise of the substrate W. The state of the stage 4 during this film forming process is illustrated in FIG. 6D.

During the film forming process, the heat insulator 451 is arranged inside the through hole 521h.

Specifically, when the stage 4 is raised to the raised position, an upper surface of the heat insulator 451 is preferably arranged at a position higher than an upper surface of the cooling plate 52. Thus, even when the temperature of the stage 4 increases due to the heat input from the plasma to the stage 4, the amount of the heat input to the cooling plate 52 through the support column 45 can be reduced.

In addition, when the stage 4 is lowered to the raised position, a lower surface of the heat insulator 451 is preferably arranged at a position lower than a lower surface of the cooling plate 52. Thus, during the film forming process, the amount of the heat input from the outside of the processing chamber 2 to the cooling plate 52 through the elevating plate 71 and the support column 45 can be reduced.

During a substrate unloading process or step, the controller 9 stops the rotation of the stage 4 by the stage rotating mechanism 6 (stage stop), and lowers the stage 4 to the lowered position (stage down) by the stage elevating mechanism 7. Then, the controller 9 moves the lift pin 46 to the raised position (pin up). Thus, the substrate W is supported by the lift pin 46. The state of the stage 4 during this stage of the substrate unloading process is the same as the state illustrated in FIG. 6B. Thereafter, the transport device receives the substrate W supported by the lift pin 46 and transports and unloads the substrate W out of the processing chamber 2. Next, the controller 9 moves the lift pin 46 to the lowered position (pin down). The state of the stage 4 during this stage of the substrate unloading process is the same as the state illustrated in FIG. 6A.

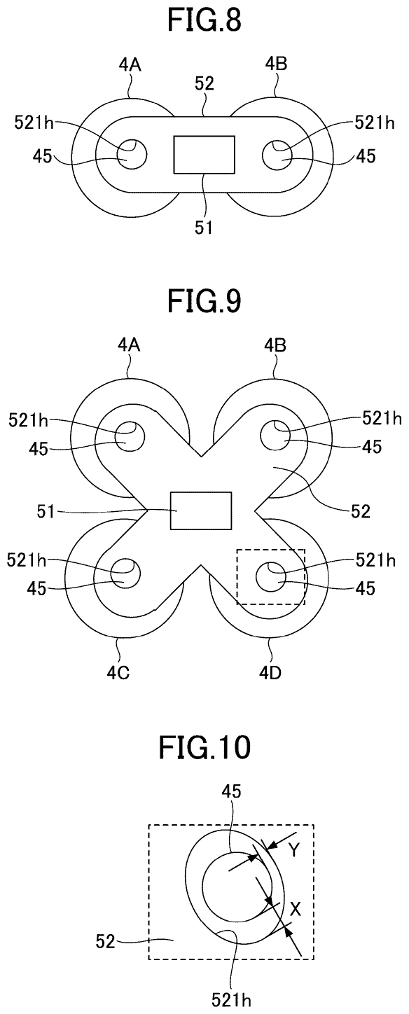

Next, the arrangement of the stage structure will be described with reference to FIG. 8 through FIG. 10.

FIG. 8 and FIG. 9 are schematic diagrams illustrating examples of the stage structure. The refrigerator 51, the cooling plate 52, and the stage 4 are extracted and illustrated in FIG. 8 and FIG. 9. FIG. 8 and FIG. 9 are plan views of the stage structure as viewed from below.

As illustrated in FIG. 8, two stages 4A and 4B may be provided with respect to one refrigerator 51. In addition, the refrigerator 51 may be arranged at a center position of a straight line connecting the centers of the plurality of through holes 521h in the plan view. The horizontal distances from the centers of the stages 4A and 4B to the center of the refrigerator 51 may be identical. Accordingly, it is possible to reduce the temperature difference between the stages 4A and 4B.

Further, as illustrated in FIG. 9, four stages 4A through 4D may be provided with respect to one refrigerator 51. In addition, the refrigerator 51 may be arranged at the center position of the straight line connecting the centers of the plurality of through holes 521h in the plan view. Further, the horizontal distances from the centers of the stages 4A through 4D to the center of the refrigerator 51 may be identical. Thus, it is possible to reduce the temperature difference among the stages 4A through 4D.

FIG. 10 is an enlarged view illustrating an example of a shape of the through hole 521h. The through hole 521h of the stage 4D indicated by a broken line in FIG. 9 will be described as an example.

In the plan view, a direction from the center of the refrigerator 51 toward the center of the support column 45 is defined as an X-direction, and a direction perpendicular to the X-direction is defined as a Y-direction. A gap between the through hole 521h and the support column 45 in the X-direction is formed larger than a gap between the through hole 521h and the support column 45 in the Y-direction. That is, the through hole 521h is an elongated hole that is elongated in a longitudinal direction extending from the center thereof toward the center of the refrigerator 51. Thus, when the cooling plate 52 thermally expands or contracts, it is possible to prevent a wall surface of the through hole 521h and the support column 45 from interfering with each other.

According to one aspect of the present disclosure, it is possible to provide a stage structure, a substrate processing apparatus, and a temperature control method for cooling a stage on which a substrate is placed.

While certain embodiments of stage structure, the substrate processing apparatus, and the temperature control method have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A stage structure comprising:
a plurality of stages respectively configured to support a substrate placed thereon;
a single cooling plate common to the plurality of stages;
a refrigerator configured to cool the cooling plate; and
an elevating device configured to thermally connect or separate a first contact surface of the plurality of stages and a second contact surface of the cooling plate.

2. The stage structure as claimed in claim 1, further comprising:
a plurality of support columns configured to support the plurality of stages, so that each support column of the plurality of support columns supports a corresponding stage of the plurality of stages,
wherein the cooling plate has a plurality of through holes through which the plurality of support columns are inserted, respectively.

3. The stage structure as claimed in claim 2, wherein the refrigerator is arranged at a center position on a straight line connecting centers of the plurality of through holes in a plan view.

4. The stage structure as claimed in claim 1, wherein horizontal distances from centers of the plurality of stages to a center of the refrigerator are identical.

5. The stage structure as claimed in claim 2, wherein the plurality through holes are elongated in a longitudinal direction extending from centers thereof toward a center of the refrigerator.

6. The stage structure as claimed in claim 2, wherein each support column of the plurality of support columns includes a heat insulator formed of heat insulating member.

7. The stage structure as claimed in claim 6, wherein upper surfaces of the heat insulators are arranged at positions higher than an upper surface of the cooling plate in a state where the plurality of stages are located at raised positions.

8. The stage structure as claimed in claim 6, wherein lower surfaces of the heat insulators are arranged at positions lower than a lower surface of the cooling plate in a state where the plurality of stages are located at raised positions.

9. The stage structure as claimed in claim 1, further comprising:
a heater configured to heat the cooling plate.

10. The stage structure as claimed in claim 9, wherein the heater includes an inner heater and an outer heater for each stage of the plurality of stages.

11. The stage structure as claimed in claim 10, wherein each stage of the plurality of stages includes:
an inner temperature sensor configured to detect a temperature of an inner region of the each stage; and
an outer temperature sensor configured to detect a temperature of an outer region of each stage.

12. A substrate processing apparatus comprising:
the stage structure according to claim 1.

13. A temperature control method for a stage structure including a first stage and a second stage respectively configured to support a substrate placed thereon, a single cooling plate common to the first stage and the second stage, a refrigerator configured to cool the cooling plate, an elevating device configured to thermally connect or separate a first contact surface of the plurality of stages and a second contact surface of the cooling plate, a first temperature sensor configured to detect a temperature of the first stage, a second temperature sensor configured to detect a temperature of the second stage, a first heater configured to heat a contact surface with the first stage, and a second heater configured to heat a contact surface with the second stage, the temperature control method comprising:
increasing an electric power supplied to the first heater or the second heater corresponding to the temperature sensor detecting a lower temperature between the first temperature sensor and the second temperature sensor.

14. A temperature control method for a stage structure including a plurality of stages respectively configured to support a substrate placed thereon, a cooling plate, a refrigerator configured to cool the cooling plate, an elevating device configured to thermally connect or separate a first contact surface of the plurality of the stages and a second contact surface of the cooling plate, and a heater configured to heat the cooling plate, the temperature control method comprising:
supplying a first electric power to the heater to thermally connect the first contact surface and the second contact surface to cool the plurality of stages;
separating the first contact surface and the second contact surface from each other; and
supplying a second electric power lower than the first electric power to the heater to thermally connect the first contact surface and the second contact surface to cool the plurality of stages.
